(19) United States
(12) Patent Application Publication
(10) Pub. No.: US 2007/0047210 A1
(43) Pub. Date: Mar. 1, 2007

(54) Assembly for an electronic component

(76) Inventor: Jose Diaz, Pembroke Pines, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/213,196

(22) Filed: Aug. 25, 2005

(51) Int. Cl. H05K 7/20

(52) U.S. Cl. 361/719

(57) ABSTRACT

An assembly (100) is provided which allows high power packaged power components (122) to operate at optimum power levels without degradation in performance. The assembly includes a heat sink (102), a printed circuit board (pcb) isolator (104) and a contact ring (106). The pcb isolator (104) provides electrical contacts (108, 128) upon which to mount the component and includes an opening (110) through which the component is soldered to the heat sink (102). The contact ring (106) is mounted to the pcb isolator (104) to form a cavity (124) within which the component (122) is contained. The assembly (100) can be coupled into a product having a chassis (320) and a product circuit board (324) such that the contact ring (106) is soldered to the product circuit board for electrical connection, and the heat sink is thermally coupled to the product chassis for heat dissipation.

### FIELD OF THE INVENTION

The present invention relates in general to active electronic components and more particularly to the packaging of such components for thermal dissipation.

### BACKGROUND OF THE INVENTION

The availability of active components for traditional communication frequencies and power levels is severely limited. Current industry standard packages for low cost, high power electronic components, such as RF power FETs (field effect transistors), are particularly poor at removing excess heat from these components.

Most low cost, injected molded packages for power FETs attempt to remove heat from the component through a metal contact in the bottom of the package. The part is soldered to a circuit board and the heat is transferred from a flag to the opposite side of the board through plated via holes. The product chassis makes contact with the opposite side of the board to draw heat away from the component. This heat dissipation technique requires that the heat be transferred from the package through a layer of solder, via holes, another solder layer, a heat spreader, thermal media (tape or paste) and the product chassis. For packages that remove heat through via holes, a degradation in power amplifier (PA) efficiency and power level has been noted for outputs over 2 watts. Thus, products requiring good thermal performance and efficiency can not use these parts. While bare, untested die can be purchased and manufactured into custom packages, vendors are reluctant to sell untested die and the manufacturing and logistical problems associated with custom packaging approaches are very costly.

Accordingly, there is a need for an improved means of facilitating heat dissipation in a high power electronic component.

### BRIEF DESCRIPTION OF THE FIGURES

The accompanying figures, where like reference numerals refer to identical or functionally similar elements throughout the separate views and which together with the detailed description below, are incorporated in and form part of the specification, serve to further illustrate various embodiments and to explain various principles and advantages all in accordance with the present invention.

FIG. 1 shows an exploded view of three pieces for an assembly in accordance with the present invention;

FIG. 2 shows a cross sectional side view of the assembly formed in accordance with the present invention;

FIG. 3 shows the cross sectional view of the assembly of FIG. 2 mounted into a product in accordance with the present invention; and

FIGS. 4 and 5 show isometric views of the completed packaging assembly formed in accordance with the present invention.

### DETAILED DESCRIPTION OF THE PREFERRED EMBODIMENT

Briefly in accordance with the present invention, there is provided herein a an assembly which takes an existing packaged high power electronic component and repackages it in an assembly that allows the heat to be removed through direct chassis contact with the top of the assembly. A high power electronic component can be operated at optimum power levels without degrading performance when contained in the assembly.

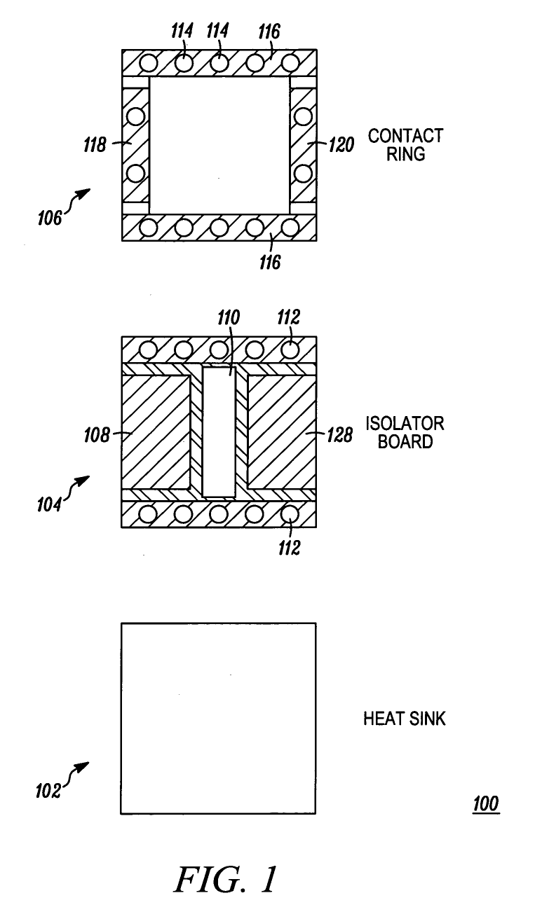

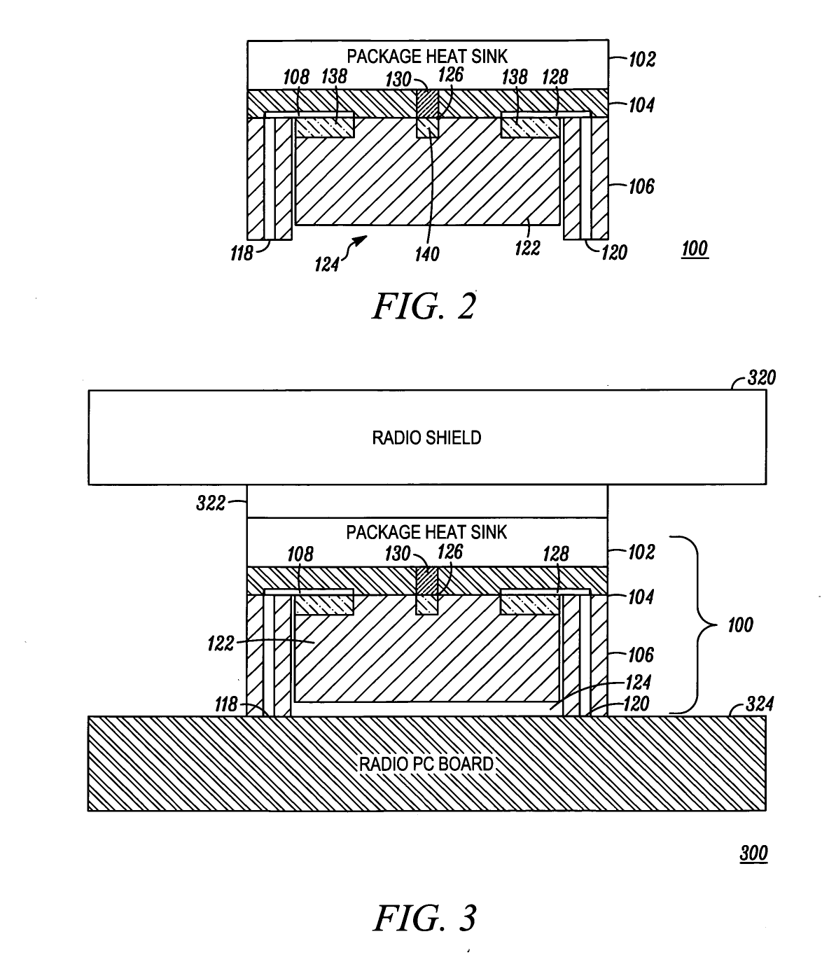

FIG. 1 shows an exploded view of three main pieces for an assembly 100 including a heat sink 102, a printed circuit board (pcb) isolator 104 and a contact ring 106 in accordance with the present invention. Printed circuit board isolator 104 includes an opening 110 through which to solder an active electronic component (shown in FIG. 2) to the heat sink 102. Printed circuit board isolator 104 also includes contact pads 108, 128 upon which to solder electronic component contacts. Via through holes 112 are formed through the pcb isolator 104 for coupling the isolator to the heat sink 102. The contact ring 106 can be formed of a cut out circuit board or the like and includes a plurality of via holes 114 formed therethrough which provide a ground interface(s) 116 and first and second active component interfaces 118, 120. Contact ring 106 has a thickness sufficient to form a cavity within which a component will sit.

Referring to FIG. 2, there is shown a cross sectional side view of the packaging assembly 100 formed in accordance with the present invention. Assembly 100 includes heat sink 102 with pcb isolator 104 soldered thereto and packaged component 122, such as a FET, soldered to the heat sink through opening 110. A tab or pedestal 130 on heat sink 102 provides a contact point upon which to solder 126 the ground contact 140 of component 122. Surface mount leads 128, 138 of component 122 are reflowed to the printed circuit board isolator's contact pads 108, 128. Contact ring 106 is soldered about the isolator board 104 creating a cavity 124 containing the packaged component 122.

FIG. 3 shows the cross sectional view of the assembly 100 mounted into a communication device 300, such as a radio, in accordance with the present invention. Communication device 300 includes a chassis 120, such as a radio shield or the like, and a communication device circuit board 124. Packaging assembly 100 is coupled between the chassis 120 and the communication device circuit board 124 with heat sink 102 being coupled to product chassis 120 using a thermal media 122, such as thermal tape or paste, while the contact ring 106 is soldered to communication device circuit board 124. The heat sink 102 makes contact through the product chassis for heat extraction. The assembly 100 of the present invention thus dissipates heat from the packaged component 122 through solder layer 126, heat sink 102, thermal media 122 and product chassis 120.

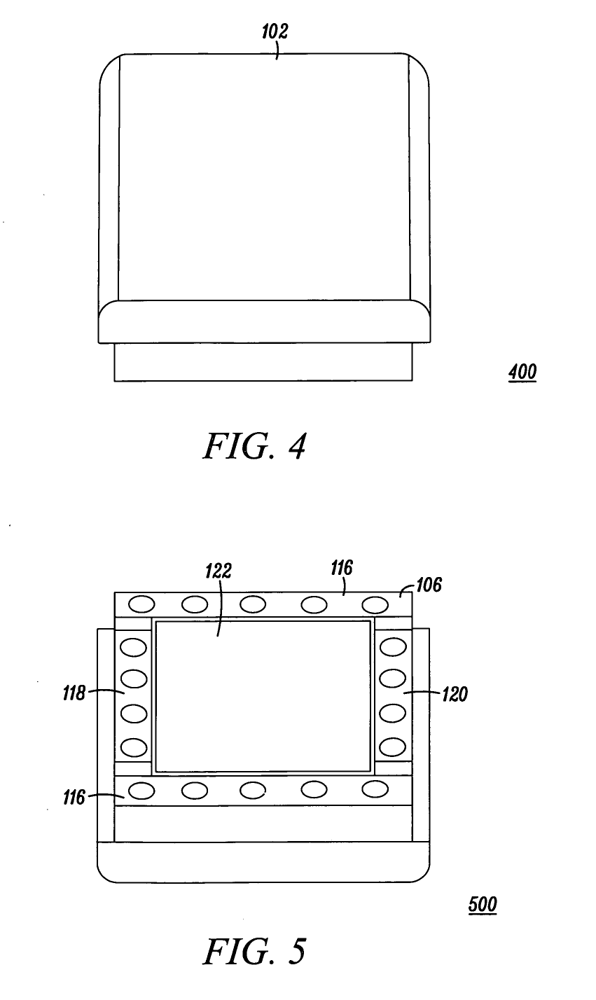

FIGS. 4 and 5 show isometric views 400, 500 of the completed packaging assembly formed in accordance with the present invention. View 400 shows the package 100 from the heat sink 102 perspective while view 500 shows the package from the contact ring 106 perspective. View 500 shows component 122 contained within the cavity 124 created by the contact ring 106. View 500 also shows ground interfaces 116 and active component interfaces 118, 120.

When a packaged electronic component is contained in an assembly formed in accordance with the present invention, optimum operating performance can be achieved. Packaging assembly 100 allows a power amplifier to operate at maximum power levels without degradation in performance. For example, the 2 watt FET mentioned in the background was operated at an optimum power level of over 10 watts without degradation in performance. The layout of the pcb isolator 104 and contact ring 106 can be configured to adapt and align to other packaged high power components as well.

The packaging assembly of the present invention allows designers to use existing, tested, packaged die in a new way to meet high tier performance standards. Thus, the need to purchase bare, untested die is eliminated. Numerous components that would otherwise be off limits to designers can now be used without having to purchase unpackaged die. By being able to purchase the components in standard packages and incorporating these standard packages into an assembly formed in accordance with the present invention manufacturability and performance issues are eliminated. The packaging assembly formed in accordance with the present invention has proven to be particularly advantageous for high power amplifiers.

While the invention has been described in conjunction with specific embodiments thereof, additional advantages and modifications will readily occur to those skilled in the art. The invention, in its broader aspects, is therefore not limited to the specific details, representative apparatus, and illustrative examples shown and described. Various alterations, modifications and variations will be apparent to those skilled in the art in light of the foregoing description. Thus, it should be understood that the invention is not limited by the foregoing description, but embraces all such alterations, modifications and variations in accordance with the spirit and scope of the appended claims.

We claim:

1. An assembly, comprising:
a packaged active component;
a heat sink;
a circuit board ring; and
a printed circuit board (pcb) isolator coupled to the heat sink, the pcb isolator having an opening through which the packaged active component is soldered to the heat sink, the contact ring being mounted to the pcb isolator to form a cavity within which the packaged active component is contained.

2. The assembly of claim 1, wherein the assembly is coupled into a product having a chassis and a product circuit board, the contact ring being soldered to the product circuit board and the heat sink being thermally coupled to the product chassis.

3. The assembly of claim 1, wherein the contact ring includes a plurality of via holes formed therethrough, the plurality of via holes providing a ground interface and first and second active component interfaces.

4. The assembly of claim 3, wherein the pcb isolator includes via holes formed therethrough for coupling to both the heat sink and the ground interface of the pcb ring.

5. The assembly of claim 3, wherein the packaged active component comprises a transistor.

6. The assembly of claim 5, wherein the transistor comprises a field effect transistor (FET).

7. An assembly, comprising:
a heat sink;
a printed circuit board (pcb) isolator coupled to the heat sink, the pcb isolator having contacts upon which to mount a packaged electronic component, and the pcb isolator having at least one opening through which to couple a ground contact of the electronic component to the heat sink; and
a contact ring coupled to the pcb isolator to create a cavity within which the electronic component is contained, the contact ring providing electrical interfaces for the assembly.

8. A communication device, comprising:
a chassis;
a communication device circuit board;
an assembly for a packaged active electronic component, the assembly coupled between the chassis and the communication device circuit board, the assembly comprising:
a circuit board ring;
a heat sink;
a printed circuit board isolator coupled between the heat sink and the circuit board ring, the packaged active electronic component being electrically coupled to the printed circuit board isolator and the heat sink, the contact ring being coupled to the printed circuit board isolator to provide a ground interface and active component interface to the communication device circuit board, and the heat sink providing a thermal dissipation path through to the chassis.

9. The communication device of claim 8, wherein the assembly further comprises:
a layer of solder coupling the contact ring to the communication device circuit board; and
a thermal media to thermally couple the heat sink to the chassis.

10. The communication device of claim 9, wherein heat is dissipated from the packaged active electronic component through the heat sink, thermal media and product chassis.

11. The communication device of claim 8, wherein the communication device comprises a radio.

12. The communication device of claim 8, wherein packaged active component comprises a transistor.
